(19) United States
(12) Patent Application Publication
(10) Pub. No.: US 2025/0194246 A1
(43) Pub. Date: Jun. 12, 2025

(54) DISPLAY PANEL AND DISPLAY APPARATUS

(71) Applicant: Hefei Visionox Technology Co., Ltd., Hefei (CN)

(72) Inventors: Jinfang ZHANG, Hefei (CN); Lu ZHANG, Hefei (CN); Miao CHANG, Hefei (CN)

(73) Assignee: Hefei Visionox Technology Co., Ltd., Hefei (CN)

(21) Appl. No.: 19/055,462

(22) Filed: Feb. 17, 2025

Related U.S. Application Data
(63) Continuation of application No. PCT/CN2024/079718, filed on Mar. 1, 2024.

(30) Foreign Application Priority Data
Jun. 29, 2023 (CN) 202310792177.9

(51) Int. Cl. H10D 86/40

(52) U.S. Cl. CPC H10D 86/441

(57) ABSTRACT

The present application discloses a display panel and a display apparatus. The display panel includes a display area and a fan-out area, and the display panel further includes: a base plate, a light-emitting layer, and a driver chip, in which the base plate includes a substrate, a first electrically conductive layer, a second electrically conductive layer, and a fan-out line located in the fan-out area, and the fan-out line includes a first wiring located in the first electrically conductive layer, and a second wiring located in the second electrically conductive layer; the light-emitting layer includes a first light-emitting unit group and a second light-emitting unit group that are arranged alternately along a second direction, the first light-emitting unit group and the second light-emitting unit group each includes multiple light-emitting units arranged along a first direction.

### CROSS REFERENCE TO RELATED APPLICATION

This application is a continuation application of International Application No. PCT/CN2024/079718, filed on Mar. 1, 2024, which claims priority to Chinese patent application No. 202310792177.9, entitled “DISPLAY PANEL AND DISPLAY APPARATUS”, filed on Jun. 29, 2023, all of which are hereby incorporated by reference in their entireties.

### FIELD

The present application relates to the field of display technology, and particularly to a display panel and a display apparatus.

### BACKGROUND

With the development of display technology, the requirements for display quality of display devices become higher and higher, and the display panel in the related art displays a vertical stripe in the displayed image, which seriously affects the display quality of the display panel.

### SUMMARY

Embodiments of the present application provide a display panel and a display apparatus, which can improve the display quality of the display panel.

Embodiments of the present application provides a display panel including a display area and a fan-out area, the display panel including:
a base plate including a substrate and a first electrically conductive layer and a second electrically conductive layer that are stacked on the substrate, in which fan-out lines are formed in the substrate, the fan-out lines are located in the fan-out area and include first wirings and second wirings, the first wirings are located in the first electrically conductive layer, and the second wiring are located in the second electrically conductive layer;
a light-emitting layer including light-emitting units formed on one side of the base plate, in which the light-emitting layer includes a first light-emitting unit group and a second light-emitting unit group, the first light-emitting unit group includes multiple light-emitting units arranged along a first direction, the second light-emitting unit group includes multiple light-emitting units arranged along the first direction, the light-emitting units in the first light-emitting unit group and the light-emitting units in the second light-emitting unit group emit light of different colors, the first light-emitting unit group and the second light-emitting unit group are arranged alternately along a second direction, and the first direction intersects with the second direction;
a driver chip located in the fan-out area;
in which the first wirings are configured to electrically connect the light-emitting units in the first light-emitting unit group with the driver chip, and the second wirings are configured to electrically connect the light-emitting units in the second light-emitting unit group with the driver chip.

Embodiments of the present application provide a display apparatus including any one of the display panels according to the embodiments of the present application.

The above display panel includes the display area and the fan-out area, the display area includes the light-emitting unit, the fan-out area includes the fan-out lines and the drive circuit, and the light-emitting unit is electrically connected with the drive circuit through the fan-out line. The fan-out lines include the first wirings and the second wirings, the first wirings are located in the first electrically conductive layer, the second wirings are located in the second electrically conductive layer, and the fan-out lines are arranged in the two electrically conductive layers, and the size of the frame of the display panel can be reduced and the wiring can be simplified. The light-emitting units are divided into the first light-emitting unit group and the second light-emitting unit group, the light-emitting units in the first light-emitting unit group and the light-emitting units in the second light-emitting unit group emit light of different colors, the light-emitting units in the first light-emitting unit group are connected with the first wiring, and the light-emitting units in the second light-emitting unit group are connected with the second wiring, and light-emitting units of the same color can be connected with the same fan-out line. Since each first wiring is located in the first electrically conductive layer, the difference between different first wirings caused by process fluctuations is relatively small. Since each second wiring is located in the second electrically conductive layer, the difference between different second wirings caused by process fluctuations is relatively small. After the light-emitting units in the first light-emitting unit group are electrically connected with the driver chip through the first wiring, and after the light-emitting units in the second light-emitting unit group are electrically connected with the driver chip through the second wiring, fan-out lines connected with light-emitting units of the same kind can be located in the same layer, and the light-emitting units of the same color have a smaller display difference caused by the difference of the fan-out lines themselves. That is, in the display panel according to the present application, light-emitting units of each color are connected with the same fan-out line (the first wiring or the second wiring), which can effectively reduce the difference in display of the light-emitting units of the same color, and the display effect of the display panel is better.

### BRIEF DESCRIPTION OF THE DRAWINGS

FIG. 1 shows a schematic structural diagram of a display panel in the related art;

FIG. 2 shows a schematic structural diagram of a display panel according to an embodiment of the present application;

FIG. 3 shows a cross-sectional diagram along P-P′ in FIG. 2;

FIG. 4 shows a cross-sectional diagram along J-J′ in FIG. 2;

FIG. 5 shows a schematic structural diagram of another display panel according to an embodiment of the present application;

FIG. 6 shows a schematic structural diagram of another display panel according to an embodiment of the present application;

FIG. 7 shows a cross-sectional diagram along Q-Q′ in FIG. 6;

FIG. 8 shows a cross-sectional diagram of another display panel according to an embodiment of the present application;

FIG. 9 shows a cross-sectional diagram of another display panel according to an embodiment of the present application;

FIG. 10 shows a schematic structural diagram of another display panel according to an embodiment of the present application;

FIG. 11 shows a schematic structural diagram of a display apparatus according to an embodiment of the present application.

### DETAILED DESCRIPTION

Features and exemplary embodiments of the present application will be described in detail below. Numerous specific details are set forth in the following detailed description to provide a thorough understanding of the present application. However, the present application may be practiced without some of these specific details. The following description of the embodiments is merely intended to provide a better understanding of the present application by illustrating examples of the present application.

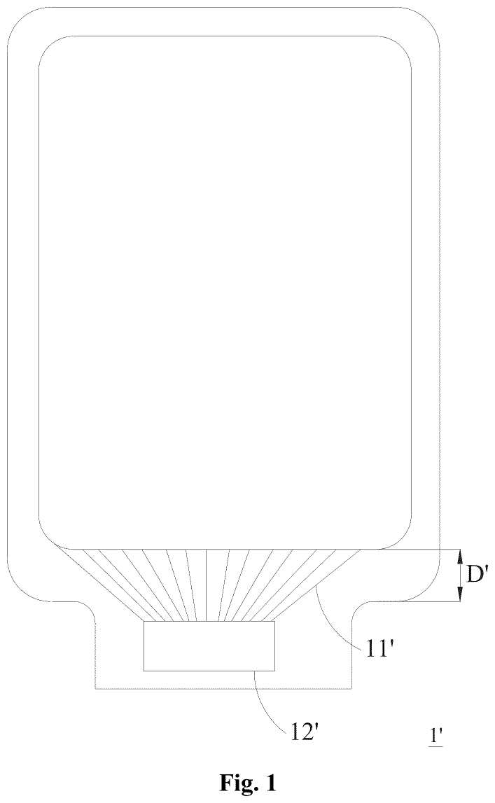

As shown in FIG. 1, a data line connected with a sub-pixel in a display panel 1′ is connected with a fan-out line 11′, and then the sub-pixel is electrically connected with the fan-out line, and the sub-pixel is electrically connected with a driver chip 12′ through the fan-out line, to drive the sub-pixel is to emit light through the driver chip 12′. However, a certain spacing should be maintained between the fan-out lines 11′, and a part of the fan-out lines 11′ corresponding to the arc angle area is relatively long and the magnitude of inclination is relatively large, and the lower frame needs to maintain a relatively large width D′ to maintain the spacing between adjacent fan-out lines 11′, and thus the spacing meets the requirements. The inventors have found that the reason for the occurrence of the vertical stripe in the display panel 1′ may be as follows. In order to realize the narrow frame of the display panel 1′ and avoid the arc angle area of the lower frame, the fan-out lines 11′ in the display panel 1′ are arranged in different layers, and the number of fan-out lines 11′ arranged in each layer can be reduced, and thus the width D′ of the lower frame can be reduced to a certain extent while maintaining a preset spacing. However, in this way, the fan-out lines 11′ connected with the sub-pixels of the same color are located in different layers. The process fluctuations between the fan-out lines 11′ located in the same layer is relatively small, and the difference between line widths of the fan-out lines 11′ located in the same layer is relatively small. The process fluctuations between the fan-out lines 11′ located in different layers is relatively large, and the difference between line widths of the fan-out lines 11′ located in different layers is relatively large. Due to the above difference between the fan-out lines 11′ of different layers, there is a difference in display of sub-pixels of the same color connected with the fan-out lines 11′ of different layers, and the vertical stripe appears in a monochrome image in the display panel 1′. Based on the study of the above problem, the inventors have provided a display panel 1′ and a display apparatus to improve the display quality of the display panel 1′.

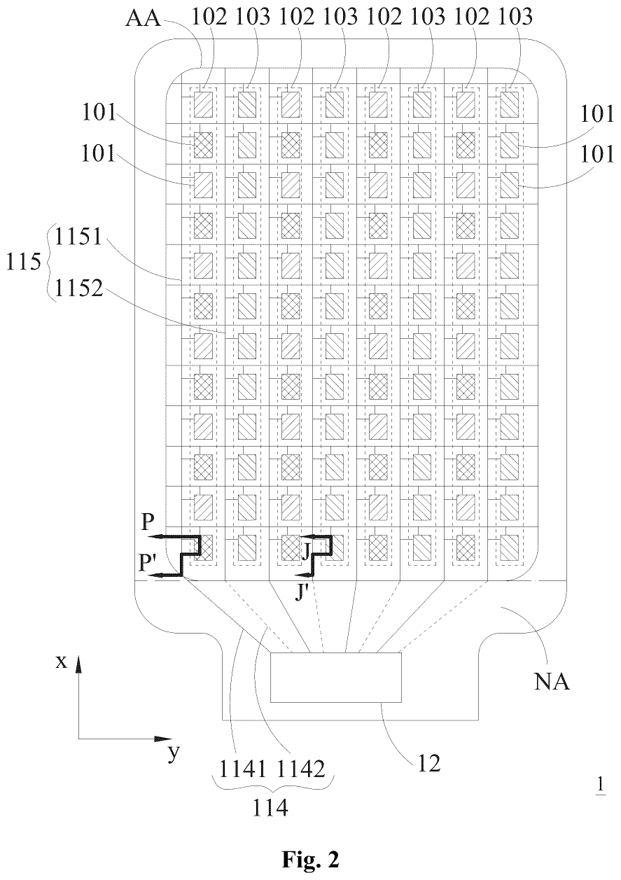

For a better understanding of the present application, a display panel and a display apparatus according to embodiments of the present application will be described in detail below with reference to FIG. 2 to FIG. 11.

Referring to FIGS. 2 to 4, the embodiments of the present application provides a display panel 1, including a display area AA and a fan-out area NA. The display panel 1 includes a base plate 11, a light-emitting layer 10, and a driver chip 12. The base plate 11 includes a substrate 111 and a first electrically conductive layer 112 and a second electrically conductive layer 113 that are stacked on the substrate 111, in which fan-out lines 114 are formed in the substrate 11, the fan-out lines 114 are located in a fan-out area NA and include first wirings 1141 and second wirings 1142, the first wirings 1141 are located in the first electrically conductive layer 112, and the second wiring 1142 are located in the second electrically conductive layer 113. The light-emitting layer 10 includes light-emitting units 101 formed on one side of the base plate 11, the light-emitting layer 10 includes a first light-emitting unit group 102 and a second light-emitting unit group 103, the first light-emitting unit group 102 includes multiple light-emitting units 101 arranged along a first direction x, the second light-emitting unit group 103 includes multiple light-emitting units 101 arranged along the first direction x, the light-emitting units 101 in the first light-emitting unit group 102 and the light-emitting units 101 in the second light-emitting unit group 103 emit light of different colors, the first light-emitting unit group 102 and the second light-emitting unit group 103 are arranged alternately along a second direction y, and the first direction x intersects with the second direction y. The driver chip 12 is located in the fan-out area NA. Herein, the first wirings 1141 are configured to electrically connect the light-emitting units 101 in the first light-emitting unit group 102 with the driver chip 12, and the second wirings 1142 are configured to electrically connect the light-emitting units 101 in the second light-emitting unit group 103 with the driver chip 12.

The above display panel 1 includes the display area AA and the fan-out area NA, the display area AA includes the light-emitting unit 101, the fan-out area NA includes the fan-out lines 114 and the drive circuit, and the light-emitting unit 101 is electrically connected with the drive circuit through the fan-out line 114. The fan-out lines 114 include the first wirings 1141 and the second wirings 1142, the first wirings 1141 are located in the first electrically conductive layer 112, the second wirings 1142 are located in the second electrically conductive layer 113, and the fan-out lines 114 are arranged in the two electrically conductive layers, and the size of the frame of the display panel 1 can be reduced and the wiring can be simplified. The light-emitting units 101 are divided into the first light-emitting unit group 102 and the second light-emitting unit group 103, the light-emitting units 101 in the first light-emitting unit group 102 and the light-emitting units 101 in the second light-emitting unit group 103 emit light of different colors, the light-emitting units 101 in the first light-emitting unit group 102 are connected with the first wiring 1141, and the light-emitting units 101 in the second light-emitting unit group 103 are connected with the second wiring 1142, and light-emitting units 101 of the same color can be connected with the same fan-out line 114. Since each first wiring 1141 is located in the first electrically conductive layer 112, the difference between different first wirings 112 caused by process fluctuations is relatively small. Since each second wiring 1142 is located in the second electrically conductive layer 113, the difference between different second wirings 1142 caused by process fluctuations is relatively small. After the light-emitting units 101 in the first light-emitting unit group 102 are electrically connected with the driver chip 12 through the first wiring 1141, and after the light-emitting units 101 in the second light-emitting unit group 103 are electrically connected with the driver chip 12 through the second wiring 1142, fan-out lines 114 connected with light-emitting units 101 of the same kind can be located in the same layer, and the light-emitting units 101 of the same color have a smaller display difference caused by the difference of the fan-out lines 114 themselves. That is, in the display panel 1 according to the present application, light-emitting units 101 of each color are connected with the same fan-out line 114 (the first wiring 1141 or the second wiring 1142), which can effectively reduce the difference in display of the light-emitting units 101 of the same color, and the display effect of the display panel 1 is better.

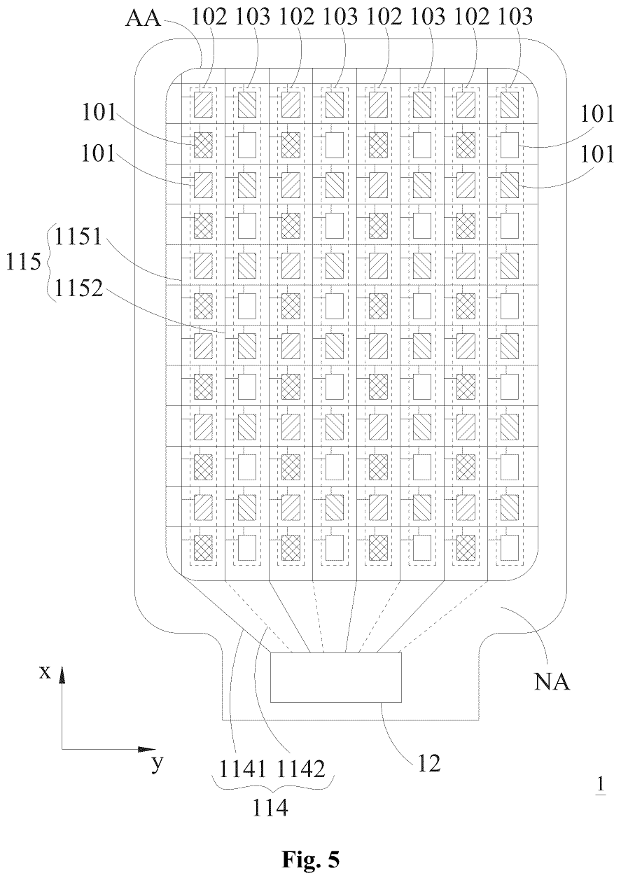

In one feasible implementation, as shown in FIGS. 2 and 5, one of the first light-emitting unit group 102 and the second light-emitting unit group 103 includes light-emitting units 101 of at least two colors, and the other one includes light-emitting units 101 of at least one color.

In one embodiment, as shown in FIG. 2, the first light-emitting unit group 102 may include light-emitting units 101 of a first color and light-emitting units 101 of a second color alternately arranged along the first direction x, and the second light-emitting unit group 103 may include light-emitting units 101 of a third color arranged along the first direction x.

In one embodiment, as shown in FIG. 2, the light-emitting unit 101 of the first color may be a red light-emitting unit 101, the light-emitting unit 101 of the second color may be a blue light-emitting unit 101, and the light-emitting unit 101 of the third color may be a green light-emitting unit 101.

Alternatively, as shown in FIG. 5, the second light-emitting unit group 103 further includes light-emitting units 101 of a fourth color, and the light-emitting units 101 of the fourth color and the light-emitting units 101 of the third color are arranged alternately along the first direction x. In this case, the light-emitting unit 101 of the first color, the light-emitting unit 101 of the second color, the light-emitting unit 101 of the third color, and the light-emitting unit 101 of the fourth color can correspond to a red light-emitting unit 101, a green light-emitting unit 101, a blue light-emitting unit 101, and a white light-emitting unit 101, and the corresponding manner is not particularly limited in the present application.

In one feasible implementation, as shown in FIGS. 2 and 5, the base plate 11 further includes data lines 115, the data lines 115 include first data lines 1151 and second data lines 1152, the first data line 1151 is electrically connected with the light-emitting units 101 in the first light-emitting unit group 102, the second data line 1152 is electrically connected with the light-emitting units 101 in the second light-emitting unit group 103, the first wirings 1141 and the first data lines 1151 are in one-to-one correspondence and electrically connected, and the second wirings 1142 and the second data lines 1152 are in one-to-one correspondence and electrically connected.

In the above display panel 1, the first wirings 1141 is configured to connect the first data line 1151 with the driver chip 12 to provide a data signal to the light-emitting units 101 in the first light-emitting unit group 102. The second wiring 1142 is configured to connect the second data line 1152 with the driver chip 12 to provide a data signal to the light-emitting units 101 in the second light-emitting unit group 103.

Herein, the base plate 11 includes a drive circuit for driving the light-emitting unit 101 to emit light, and the driving circuit is respectively connected with the light-emitting unit 101 and the data line 115.

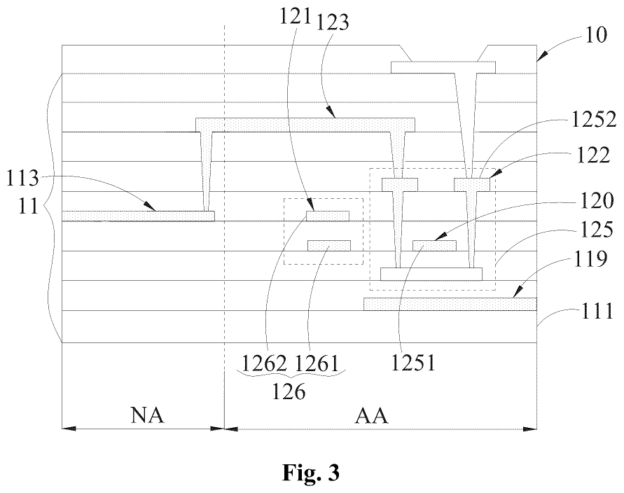

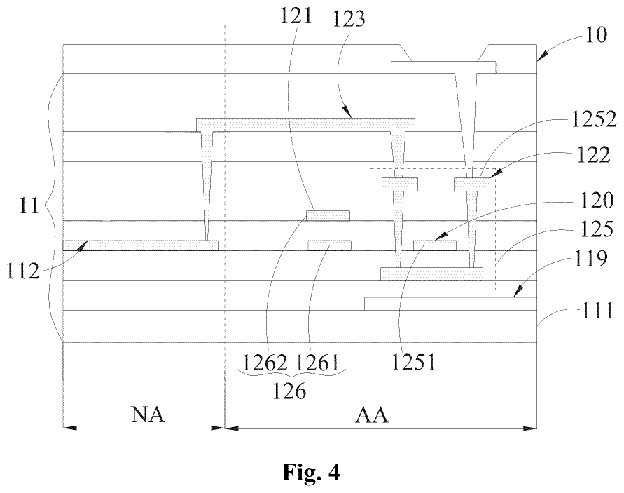

In one feasible implementation, as shown in FIGS. 3 and 4, the base plate 11 includes the substrate 111 and a first metal layer 119, a second metal layer 120, a third metal layer 121, a fourth metal layer 122, a fifth metal layer 123, and a sixth metal layer 124 that are stacked in a direction away from the substrate 111, the base plate 11 includes a transistor 125 and a capacitor 126, and the drive circuit for driving the light-emitting unit 101 to emit light includes the above transistor 125 and capacitor 126.

The first metal layer 119 is located between the substrate 111 and the transistor 125, and configured as a shielding metal layer to protect the performance of the transistor 125.

The second metal layer 120 is configured to form a gate 1251 of the transistor 125 and a first electrode plate 1261 of the capacitor 126.

The third metal layer 121 is configured to form a second electrode plate 1262 of the capacitor 126.

The fourth metal layer 122 is configured to form a source and a drain 1252 of the transistor 125.

The fifth metal layer 123 and the sixth metal layer 124 are configured to form the data line 115.

The first electrically conductive layer 112 is arranged in the same layer as one of the first metal layer 119, the second metal layer 120, and the third metal layer 121, and the second electrically conductive layer 113 is arranged in the same layer as another one of the first metal layer 119, the second metal layer 120, and the third metal layer 121.

In the above implementation, the first wiring 1141 may be located in one of the first metal layer 119, the second metal layer 120, and the third metal layer 121, and the second wiring 1142 may be located in another one of the first metal layer 119, the second metal layer 120, and the third metal layer 121. The first wiring 1141 and the second wiring 1142 may be electrically connected with the data line 115 through a via.

As shown in FIG. 4, the first electrically conductive layer 112 is arranged in the same layer as the second metal layer 120. As shown in FIG. 3, the second electrically conductive layer 113 is arranged in the same layer as the third metal layer 121. Other cases are not shown in the figures.

In one feasible implementation, the base plate 11 includes a third electrically conductive layer 116 and a fourth electrically conductive layer 117 that are located at a side of the second electrically conductive layer 113 away from the substrate 111 and stacked, and the data lines 115 are located in the third electrically conductive layer 116 or the fourth electrically conductive layer 117.

In one feasible implementation, as shown in FIG. 4, the third electrically conductive layer 116 is arranged in the same layer as the fifth metal layer 123, and the fourth electrically conductive layer 117 is arranged in the same layer as the sixth metal layer 124.

In the above implementation, the data line 115 is arranged in the fifth metal layer 123 or the sixth metal layer 124, and devices such as the transistor 125, the capacitor 126, and the like, that are located in the second metal layer 120, the third metal layer 121, and the fourth metal layer 122 can be avoided from the data line 115.

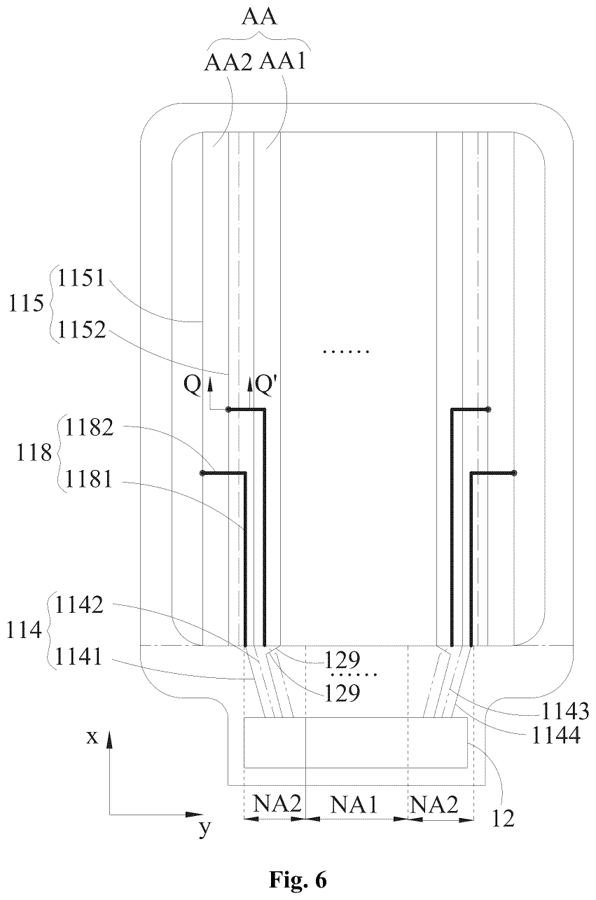

In one feasible implementation, as shown in FIG. 6, the display area AA includes a middle area AA1 and two edge areas AA2 respectively located at two sides of the middle area AA1 along the second direction y, and in which along the first direction x, an orthographic projection of the fan-out line 114 on the display area AA is located in the middle area AA1, the first data line 1151 and the second data line 1152 in the edge area AA2 are each connected with the fan-out line 114 through a first connection portion 118, and the first connection portion 118 is at least partially located in the display area AA.

In the above implementation, the display panel 1 may include an arc angle area, the arc angle area is arranged opposite to the edge area AA2 along the first direction x, and the space of the arc angle area is relatively small. Therefore, in one implementation, the fan-out line 114 may be partially located in the arc angle area and arranged obliquely, but the fan-out line 114 arranged obliquely occupy more space than the fan-out line 114 arranged parallel to the first direction x, which is not beneficial for achieving a narrow frame design. Therefore, in another implementation, as shown in FIG. 6, the fan-out line 114 is concentrated in an area arranged opposite to the middle area AA1 along the first direction x, the fan-out line 114 is electrically connected with the data line 115 through the first connection portion 118, and the first connection portion 118 is at least partially located in the display area AA, to effectively solve the above interference on the wiring of the fan-out line 114 due to the small space of the arc angle area, and help to achieve the narrow frame.

In one feasible implementation, as shown in FIG. 6, the first connection 118 includes a first section 1181 and a second section 1182, the first section 1181 is parallel to the first direction x, the second section 1182 is parallel to the second direction y, the first section 1181, and an orthographic projection of the first section 1181 on the substrate 111 is spaced apart from an orthographic projection of the data line 115 on the substrate 111. On one hand, the first connection 118 includes the two parts extending along the first direction x and the second direction y, which may facilitate wiring. On the other hand, the first connection portion 118 increases the reflection of light, and the distribution range of the first connection portion 118 may be increased by designing the first connection portion 118 as the first section 1181 and the second section 1182, to improve the display uniformity of the display area AA.

In the above implementation, the first connection portion 118 is located in the third electrically conductive layer 116 or the fourth electrically conductive layer 117, and the first connection portion 118 is arranged in a different layer from the data line 115.

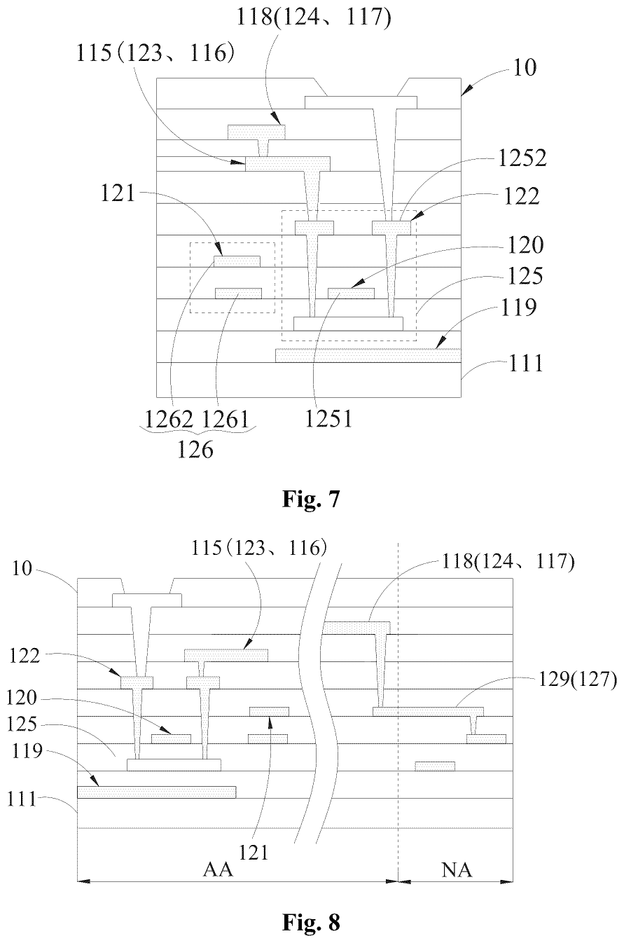

In the above implementation, as shown in FIGS. 6 and 7, the third electrically conductive layer 116 is arranged in the same layer as the fifth metal layer 123, and the fourth electrically conductive layer 117 is arranged in the same layer as the sixth metal layer 124, and thus the first connection portion 118 is formed in the fifth metal layer 123 or the sixth metal layer 124, and is arranged in a different layer from the data line 115. In one embodiment, FIG. 7 shows the case where the data line 115 is located in the fifth metal layer 123 and the first connection portion 118 is located in the sixth metal layer 124. Alternatively, the data line 115 may be located in the sixth metal layer 124, and the first connection 118 may be located in the fifth metal layer 123, which is not shown in the figures. Since the first connection portion 118 is configured to connect the data line 115 and the fan-out line 114, and the first connection portion 118 is at least partially located in the display area AA, while the first connection portion 118 connects the data line 115 located in the edge area AA2 and the fan-out line 114 arranged opposite the middle area AA1, the first connection portion 118 will extend from the edge area AA2 to the middle area AA1 in the display area AA. Therefore, the first connection portion 118 needs to be arranged in a different layer from the data line 115, otherwise, the data line 115 will be disturbed, and the electrical insulation from the data line 115 cannot be achieved.

In one embodiment, the first connection portion 118 may be located in a different layer from the data line 115, each data line 115 is located in the same layer, and the first connection portion 118 is connected with the data line 115 through a via. An extension direction of the first section 1181 is the same as an extension direction of the data line 115. However, since the space between adjacent data lines 115 is limited, arranging the first section 1181 in the same layer as the data line 115 will cause the spacing between the first section 1181 and an adjacent data line 115 to be too small. On the one hand, the difficulty in wiring will be increased, and on the other hand, mutual interference between the first section 1181 and the data line 115 will be caused. Therefore, in the above implementation, the first section 1181 is arranged in a different layer from the data line 115, and the orthographic projection of the first section 1181 on the substrate 111 is spaced apart from the orthographic projection of the data line 115 on the substrate 111. On the one hand, the adverse effect on wiring caused by the relatively small spacing between the first section 1181 and the data line 115 can be avoided, and on the other hand, the signal interference between the first section 1181 and the data line 115 can be reduced. Since the second section 1182 intersects with the extending direction of the data line 115 and cannot be located in the same layer as the data line 115, the second section 1182 is arranged in a different layer from the data line 115. The first section 1181 and the second section 1182 are located in the same layer, and the number of film layers in the display panel 1 can be reduced and the thickness of the display panel 1 can be reduced.

In one feasible embodiment, as shown in FIG. 6, an orthographic projection of the first wiring 1141 on the substrate 111 is spaced apart from an orthographic projection of the second wiring 1142 on the substrate 111.

In the above implementation, the first wiring 1141 and the second wiring 1142 are arranged in different electrically conductive layers, and the requirement for wiring space in each plane is reduced by increasing the wiring space in spatial category, and each fan-out line 114 can be arranged in the area opposite to the middle area AA1 of the display area AA, without occupying the space for the arc angle and facilitating the implementation of the narrow frame. While the orthographic projection of the first wiring 1141 on the substrate 111 is spaced from the orthographic projection of the second wiring 1142 on the substrate 111, namely, the orthographic projection of the first wiring 1141 on the substrate 111 and the orthographic projection of the second wiring 1142 on the substrate 111 are arranged alternately, and the mutual interference between the first wiring 1141 and the second wiring 1142 in the direction perpendicular to the substrate 111 can be reduced. In addition, the orthographic projection of the first wiring 1141 on the substrate 111 and the orthographic projection of the second wiring 1142 on the substrate 111 are arranged alternately, which helps to improve the space utilization rate of wiring.

In one feasible implementation, as shown in FIG. 6, at least a part of the fan-out line 114 is connected with the data line 115 through a second connection portion 129.

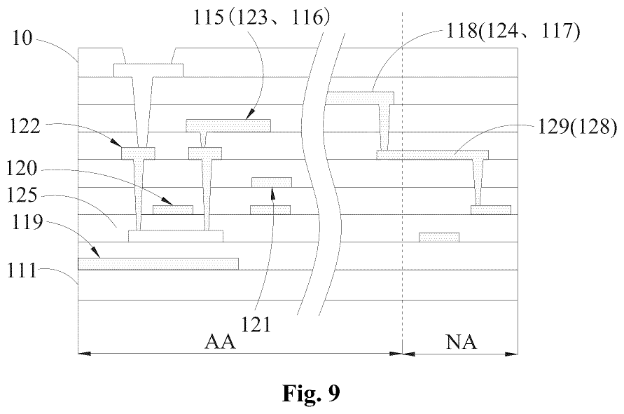

In the above implementation, as shown in FIGS. 8 and 9, the base plate 11 further includes a fifth electrically conductive layer 127 and a six electrically conductive layer 128 that are stacked on the first electrically conductive layer 112 and the second electrically conductive layer 113 and are electrically insulated form the first electrically conductive layer 112 and the second electrically conductive layer 113, the second connection portion 129 is located in the fifth electrically conductive layer 127 or the six electrically conductive layer 128, the second connection portion 129 is arranged in a different layer from the first wiring 1141 and the second wiring 1142, and the second connection portion 129 is connected with the fan-out line 114 through a via.

In one embodiment, the first electrically conductive layer 112 is arranged in the same layer as one of the first metal layer 119, the second metal layer 120, and the third metal layer 121, and the second electrically conductive layer 113 is arranged in the same layer as another one of the first metal layer 119, the second metal layer 120, and the third metal layer 121. That is, the first wiring 1141 is located in the same layer as one of the first metal layer 119, the second metal layer 120, and the third metal layer 121, and the second wiring 1142 is located in the same layer as another one of the first metal layer 119, the second metal layer 120, and the third metal layer 121. In one embodiment, the first wiring 1141 and the second wiring 1142 are each connected with the data line 115 through the second connection portion 129, and the second connection portion 129 is arranged in a different layer from the fan-out line 114, and thus interference with the first wiring 1141 and the second wiring 1142 can be prevented.

In one embodiment, as shown in FIGS. 8 and 9, the fifth electrically conductive layer 127 is located in the same layer as the third metal layer 121, and the sixth electrically conductive layer 128 is located in the same layer as the fourth metal layer 122.

In one feasible implementation, as shown in FIGS. 8 and 9, the first wiring 1141 is arranged in the same layer as one of the first metal layer 119 and the second metal layer 120, and the second wiring 1142 is arranged in the same layer as the other one of the first metal layer 119 and the second metal layer 120. In this case, the second connection portion 129 may be arranged in the fifth electrically conductive layer 127 or the sixth electrically conductive layer 128, i.e., in the same layer as the third metal layer 121 or the fourth metal layer 122, to prevent the second connection portion 129 from interfering with the wiring of the fan-out line 114.

In another feasible implementation, the first wiring 1141 is arranged in the same layer as one of the first metal layer 119, the second metal layer 120, and the third metal layer 121, and the second wiring 1142 is arranged in the same layer as another one of the first metal layer 119, the second metal layer 120, and the third metal layer 121. In this case, the second connection portion 129 may be arranged in the sixth electrically conductive layer 128, i.e., in the same layer as the fourth metal layer 122, to prevent the second connection portion 129 from interfering with the wiring of the fan-out line 114. In the above implementation, the fifth electrically conductive layer 127 is spaced apart from both the first electrically conductive layer 112 and the second electrically conductive layer 113 by a relatively great distance in the direction perpendicular to the substrate 111, and the sixth electrically conductive layer 128 is spaced apart from both the first electrically conductive layer 112 and the second electrically conductive layer 113 by a relatively great distance in the direction perpendicular to the substrate 111, and the mutual interference between the second connection portion 129 and the fan-out line 114 located below the second connection portion 129 can be reduced.

In one feasible implementation, as shown in FIG. 6, orthographic projections of the first wiring 1141 and the second wiring 1142 on the substrate 111 are arranged alternately along the second direction y, the fan-out area NA includes a first area NA1 and two second areas NA2, the second areas NA2 are respectively located at two sides of the first area NA1 in the second direction y, the fan-out lines 114 include at least one of middle fan-out line 1143 and edge fan-out lines 1144, the middle fan-out line 1143 is configured to be connected with the light-emitting units 101 in the middle area AA1, the edge fan-out line 1144 is configured to be connected with the light-emitting units 101 in the edge area AA2, and the edge fan-out lines 1144 are located in the second area NA2.

In the above implementation, the fan-out line 114 includes the middle fan-out line 1143 configured to be connected with the light-emitting units 101 in the middle area AA1 and the edge fan-out line 1144 configured to be connected with the light-emitting units 101 in the edge area AA2, in which a part of the middle fan-out line 1143 may extend along the first direction x, and the edge fan-out line 1144 and the other part of the middle fan-out line 1143 may extend along a direction intersecting with the first direction x and the second direction y.

In the above implementation, the fan-out area NA includes the first area NA1 and the second areas NA2, the second areas NA2 respectively located at two sides of the first area NA1 in the second direction y, and the edge fan-out lines 1144 are located in the second area NA2.

The edge fan-out lines 1144 are arranged in two edge areas of the fan-out area NA along the second direction y, to achieve the connection of the light-emitting units 101 in the edge area AA2, which can save the length of the edge fan-out line 1144 compared to the connection of the light-emitting units 101 in the edge area AA2 through the fan-out line 114 in the middle of the fan-out area NA, thereby not only reducing the resistance and power consumption, but also facilitating wiring.

In the above implementation, three fan-out lines 114 at least partially adjacent along the second direction y include an edge fan-out line 1144, in which the fan-out lines 114 at least partially adjacent along the second direction y refer to orthographic projection of the fan-out lines 114 on the substrate 111 are adjacent along the second direction y. The above arrangement can enable the edge fan-out line 1144 to be arranged in the second area NA2, while enabling the first light-emitting unit group 102 in the edge area AA2 to be connected with the first wiring 1141, and the second light-emitting unit group 103 to be connected with the second wiring 1142.

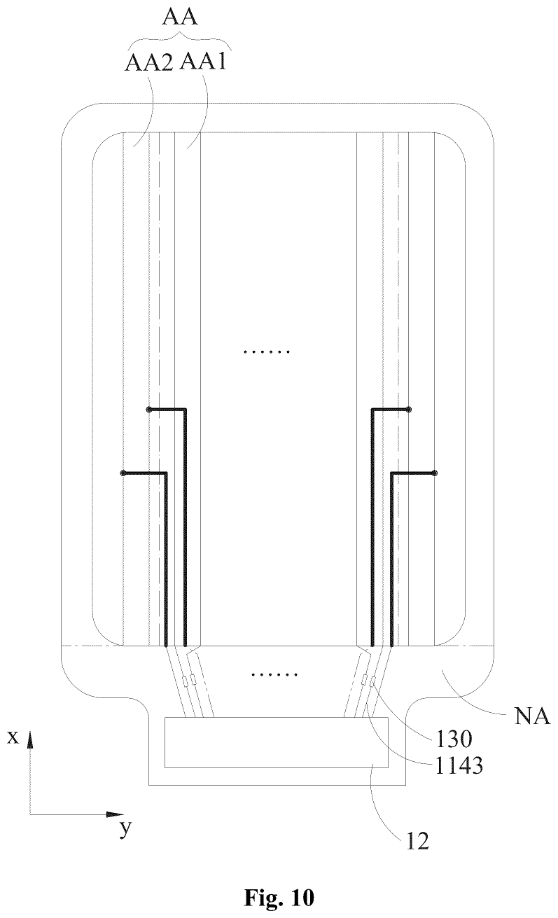

In one feasible implementation, as shown in FIG. 10, the base plate 11 further includes compensation resistor 130, and the middle fan-out lines 1143 are connected with the compensation resistors 130 in one-to-one correspondence.

Since the edge fan-out line 1144 is connected with the data line 115 through the first connection portion 118, the resistance in the circuit corresponding to the edge fan-out line 1144 is increased, to cause a difference between the data signal received by the light-emitting unit 101 in the edge area AA2 and the data signal received by the light-emitting unit 101 in the middle area AA1 in the display panel 1, to cause display uniformity. By connecting the compensation resistor 130 to the middle fan-out line 1143 connected with the data line 115 in the middle area AA1, the display difference of the display panel 1 can be reduced and the display quality can be further improved.

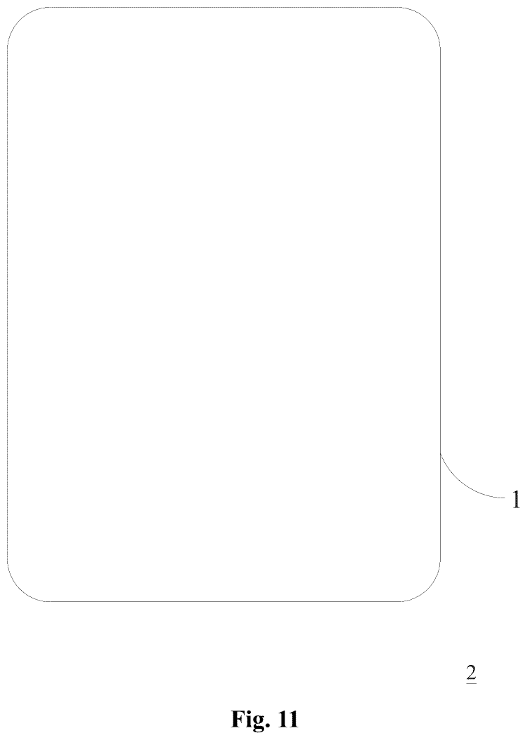

The present application further provides a display apparatus 2, as shown in FIG. 11, and the display apparatus 2 includes any of the display panel 1 according to the above implementations of the present application.

Since the display apparatus 2 according to the present application includes the display panel 1 according to any of the above embodiments, the display apparatus 2 according to the present application has the beneficial effects of the display panel 1 according to any of the above embodiments, which will not be repeated herein.

The display apparatus 2 in the embodiments of the present application includes, but is not limited to, a cellular phone, a Personal Digital Assistant (PDA), a tablet computer, an e-book, a television, an entrance guard, a smart fixed-line phone, a console, and other apparatus with display function.

The above embodiments of the present application do not exhaustively describe all the details, nor do they limit the present application to the specific embodiments as described. According to the above description, many modifications and changes can be made. These embodiments are selected and particularly described in the specification to better explain the principles and practical applications of the present application to utilize the present application and make modifications based on the present application. The present application is limited only by the claims and the full scope and equivalents of the claims.

What is claimed is:

1. A display panel comprising a display area and a fan-out area, the display panel comprising:
a base plate comprising a substrate and a first electrically conductive layer and a second electrically conductive layer that are stacked on the substrate, wherein a plurality of fan-out lines are formed in the substrate, the plurality of fan-out lines are located in the fan-out area and comprise a plurality of first wirings and a plurality of second wirings, the plurality of first wirings are located in the first electrically conductive layer, and the plurality of second wirings are located in the second electrically conductive layer;
a light-emitting layer comprising a plurality of light-emitting units formed on one side of the base plate, wherein the light-emitting layer comprises a first light-emitting unit group and a second light-emitting unit group, the first light-emitting unit group comprises multiple light-emitting units arranged along a first direction, the second light-emitting unit group comprises multiple light-emitting units arranged along the first direction, the light-emitting units in the first light-emitting unit group and the light-emitting units in the second light-emitting unit group emit light of different colors, the first light-emitting unit group and the second light-emitting unit group are arranged alternately along a second direction, and the first direction intersects with the second direction; and
a driver chip located in the fan-out area;
wherein the first wirings are configured to electrically connect the light-emitting units in the first light-emitting unit group with the driver chip, and the second wirings are configured to electrically connect the light-emitting units in the second light-emitting unit group with the driver chip.

2. The display panel according to claim 1, wherein the base plate further comprises a plurality of data lines, the plurality of data lines comprise a plurality of first data lines and a plurality of second data lines, the first data line is electrically connected with the light-emitting units in the first light-emitting unit group, the second data line is electrically connected with the light-emitting units in the second light-emitting unit group, the plurality of first wirings and the plurality of first data lines are in one-to-one correspondence and electrically connected, and the plurality of second wirings and the plurality of second data lines are in one-to-one correspondence and electrically connected.

3. The display panel according to claim 2, wherein the base plate comprises a third electrically conductive layer and a fourth electrically conductive layer that are located at a side of the second electrically conductive layer away from the substrate and stacked, and the data lines are located in the third electrically conductive layer or the fourth electrically conductive layer.

4. The display panel according to claim 3, wherein the display area comprises a middle area and two edge areas respectively located at two sides of the middle area along the second direction, and wherein along the first direction, an orthographic projection of the fan-out lines on the display area is located in the middle area, the first data line and the second data line in the edge area are each connected with the fan-out line through a first connection portion, and the first connection portion is at least partially located in the display area.

5. The display panel according to claim 4, wherein the first connection portion is located in the third electrically conductive layer or the fourth electrically conductive layer, and the first connection portion is arranged in a different layer from the data line.

6. The display panel according to claim 5, wherein at least a part of the fan-out line is connected with the data line through a second connection portion.

7. The display panel according to claim 5, wherein the first connection portion comprises a first section and a second section, the first section is parallel to the first direction, the second section is parallel to the second direction, and an orthographic projection of the first section on the substrate is spaced apart from an orthographic projection of the data line on the substrate.

8. The display panel according to claim 7, wherein an orthographic projection of the first wiring on the substrate is spaced apart from an orthographic projection of the second wiring on the substrate.

9. The display panel according to claim 7, wherein an extending direction of the first section is the same as an extending direction of the data line.

10. The display panel according to claim 7, wherein the second section is arranged in a different layer from the data line.

11. The display panel according to claim 7, wherein the first section and the second section are located in the same layer.

12. The display panel according to claim 6, wherein
the base plate comprises the substrate and a first metal layer, a second metal layer, a third metal layer, a fourth metal layer, a fifth metal layer, and a sixth metal layer that are stacked in a direction away from the substrate, and the base plate comprises a transistor and a capacitor, wherein:
the first metal layer is located between the substrate and the transistor;
the second metal layer is configured to form a gate of the transistor and a first electrode plate of the capacitor;
the third metal layer is configured to form a second electrode plate of the capacitor;
the fourth metal layer is configured to form a source and a drain of the transistor; and
the fifth metal layer and the sixth metal layer are configured to form the data line.

13. The display panel according to claim 12, wherein the first electrically conductive layer is arranged in the same layer as one of the first metal layer, the second metal layer, and the third metal layer, and the second electrically conductive layer is arranged in the same layer as another one of the first metal layer, the second metal layer, and the third metal layer.

14. The display panel according to claim 13, wherein the third electrically conductive layer is arranged in the same layer as the fifth metal layer, and the fourth electrically conductive layer is arranged in the same layer as the sixth metal layer.

15. The display panel according to claim 14, wherein
the base plate further comprises a fifth electrically conductive layer and a six electrically conductive layer that are stacked on the first electrically conductive layer and the second electrically conductive layer and are electrically insulated form the first electrically conductive layer and the second electrically conductive layer, the second connection portion is located in the fifth electrically conductive layer or the six electrically conductive layer, the second connection portion is arranged in a different layer from the first wiring and the second wiring, and the second connection portion is connected with the fan-out line through a via.

16. The display panel according to claim 15, wherein
the fifth electrically conductive layer is located in the same layer as the third metal layer, and a sixth electrically conductive layer is located in the same layer as the fourth metal layer.

17. The display panel according to claim 6, wherein orthographic projections of the first wiring and the second wiring on the substrate are arranged alternately along the second direction, the fan-out area comprises a first area and two second areas, the second areas respectively located at two sides of the first area in the second direction, the fan-out lines comprise at least one of middle fan-out line and a plurality of edge fan-out lines, the middle fan-out line is configured to be connected with the light-emitting units in the middle area, the edge fan-out line is configured to be connected with the light-emitting units in the edge area, and the edge fan-out lines are located in the second area.

18. The display panel according to claim 17, wherein the base plate further comprises a plurality of compensation resistors, and the plurality of middle fan-out lines are connected with the plurality of compensation resistors in one-to-one correspondence.

19. The display panel according to claim 1, wherein one of the first light-emitting unit group and the second light-emitting unit group comprises light-emitting units of at least two colors, and the other one comprises light-emitting units of at least one color.

20. A display apparatus, comprising:
a display panel comprising a display area and a fan-out area, the display panel comprising:
a base plate comprising a substrate and a first electrically conductive layer and a second electrically conductive layer that are stacked on the substrate, wherein a plurality of fan-out lines are formed in the substrate, the plurality of fan-out lines are located in the fan-out area and comprise a plurality of first wirings and a plurality of second wirings, the plurality of first wirings are located in the first electrically conductive layer, and the plurality of second wirings are located in the second electrically conductive layer;
a light-emitting layer comprising a plurality of light-emitting units formed on one side of the base plate, wherein the light-emitting layer comprises a first light-emitting unit group and a second light-emitting unit group, the first light-emitting unit group comprises multiple light-emitting units arranged along a first direction, the second light-emitting unit group comprises multiple light-emitting units arranged along the first direction, the light-emitting units in the first light-emitting unit group and the light-emitting units in the second light-emitting unit group emit light of different colors, the first light-emitting unit group and the second light-emitting unit group are arranged alternately along a second direction, and the first direction intersects with the second direction; and
a driver chip located in the fan-out area;
wherein the first wirings are configured to electrically connect the light-emitting units in the first light-emitting unit group with the driver chip, and the second wirings are configured to electrically connect the light-emitting units in the second light-emitting unit group with the driver chip.
